(19) United States
(12) Patent Application Publication
(10) Pub. No.: US 2007/0024304 A1
(43) Pub. Date: Feb. 1, 2007

(54) Wafer holder, heater unit used for wafer prober and having wafer holder, and wafer prober

(76) Inventors: Katsuhiro Itakura, Itami-shi (JP); Masuhiro Natsuhara, Itami-shi (JP); Tomoyuki Awazu, Itami-shi (JP); Hirohiko Nakata, Itami-shi (JP)

Correspondence Address: MCDERMOTT WILL & EMERY LLP, 600 13TH STREET, N.W., WASHINGTON, DC, 20005-3096, US

(21) Appl. No.: 11/492,196

(22) Filed: Jul. 25, 2006

(30) Foreign Application Priority Data
Jul. 25, 2005 (JP) 2005-213831 (P)

(51) Int. Cl. G01R 31/02

(52) U.S. Cl. 324/760

(57) ABSTRACT

Noise leakage from a heater body can be reduced by a wafer holder including a chuck top for mounting a semiconductor wafer, provided with the heater body, and a supporter supporting the chuck top, at least partially covered with a metal member, and by a heater unit for a wafer prober and the wafer prober using the wafer holder. In the wafer holder in accordance with the present invention, the metal member covers the supporter, preferably apart from the supporter by a distance of at most 5 mm, more preferably at most 1 mm and particularly preferably at most 0.2 mm.

### BACKGROUND OF THE INVENTION

1. Field of the Invention

The present invention relates to a wafer holder and a heater unit used for a wafer prober in which a semiconductor wafer is mounted on a wafer-mounting surface and a probe card is pressed onto the wafer for inspecting electric characteristics of the wafer, as well as to a wafer prober having these mounted thereon.

2. Description of the Background Art

Conventionally, in the step of inspecting a semiconductor wafer, the semiconductor wafer as an object of processing is subjected to heat treatment. Here, burn-in process is performed in which the semiconductor wafer is heated to a temperature higher than the temperature of normal use, to accelerate degradation of a possibly defective semiconductor chip and to remove the defective chip, in order to prevent defects after shipment.

In the burn-in process, before cutting the semiconductor wafer having circuits formed thereon into individual semiconductor chips, electrical characteristics of each semiconductor chip are measured and defective ones are removed while the semiconductor wafer is heated. In the burn-in process, reduction of process time is strongly desired in order to improve throughput.

In the burn-in process as such, a wafer holder containing a heater for heating the semiconductor wafer and provided with a chuck top for mounting the semiconductor wafer is used. In the conventional wafer holder, a flat metal plate has been used as the chuck top, as it is necessary to have the entire rear surface of the semiconductor wafer in contact with the ground electrode.

In the burn-in process, a semiconductor wafer having circuits formed thereon is mounted on the chuck top of the wafer holder, and electric characteristics of the semiconductor chips are measured. At the time of measurement of electric characteristics of the semiconductor chips, a probe referred to as a probe card having a number of probe pins for electric conduction is pressed onto the semiconductor wafer with a force of several tens to several hundreds kgf. Therefore, when the chuck top is thin, the chuck top might possibly be deformed, resulting in contact failure between the semiconductor wafer and a probe pin. In order to prevent such a contact failure, it is necessary to use a thick metal plate having the thickness of at least 15 mm for the chuck top, for maintaining rigidity of the chuck top and the wafer holder. When such a thick metal plate is used, however, it takes long time to increase and decrease temperature of the semiconductor wafer, which is a significant drawback in improving the throughput.

In the burn-in process, the semiconductor chip is electrically conducted and electric characteristics are measured. As recent semiconductor chips come to have higher outputs, it is possible that a semiconductor chip generates considerable heat during measurement of electric characteristics, and in some situations, a semiconductor chip might be broken by self-heating. Therefore, after measurement, rapid cooling is required. During measurement, heating as uniform as possible is required. In view of the foregoing, high copper (Cu) having thermal conductivity as high as 403 W/mK has been used as a material for the chuck top.

Japanese Patent Laying-Open No. 2001-033484 (Patent Document 1) proposes a wafer holder having a thin metal layer (chuck top conductive layer) formed on a ceramic substrate that is thin but having high rigidity and is not susceptible to deformation, in place of a chuck top of thick metal plate. According to Patent Document 1, as the wafer holder has high rigidity, contact failure between the semiconductor wafer and the probe pin can be avoided, and as it has small thermal capacity, temperature of the semiconductor wafer can be increased and decreased. Further, it is described that an aluminum alloy or stainless steel may be used as a support base for the wafer holder.

As described in Patent Document 1, however, when only the outermost circumference of the wafer holder is supported by the support base, the wafer holder itself may warp as it is pressed by the probe card, and therefore, it has been necessary to devise measures to support the wafer holder by, for example, a number of pillars, in addition to the support base.

Further, the semiconductor wafer is heated when probed, and therefore, typically, a heater body is provided with the wafer holder. The heater body, however, generates noise, and particularly during probing at a high frequency, the noise sometimes poses a problem for probing. Particularly when the heater body is formed on a bottom surface side of the chuck top for heating from the bottom surface and the supporter of the chuck top is of an insulator, the noise generated by the heater body tends to affect probing.

### SUMMARY OF THE INVENTION

The present invention was made to solve the above-described problems, and its object is to provide a wafer holder having noise leakage from a heater body reduced, and to provide a heater unit for a wafer prober and a wafer prober using the same.

Another object of the present invention is to provide a wafer holder capable of reducing noise leakage at a low cost particularly when the supporter is an insulator and the noise leakage from the heater body much affects probing, and to provide a heater unit for a wafer prober and a wafer prober using the same.

The inventors have found that, in a wafer holder including a chuck top for mounting a semiconductor wafer and having a heater body provided thereon and a supporter supporting the chuck top, the noise can be reduced when at least a part of said supporter is covered with a metal member.

Specifically, the wafer holder of the present invention is characterized in that it includes: a chuck top for mounting a semiconductor wafer, provided with a heater body; and a supporter supporting the chuck top, at least partially covered with a metal member.

By the wafer holder of the present invention as described above, the influence of noise can be minimized, and therefore, highly accurate measurement is possible even by probing at a high frequency.

Here, the metal member covers the supporter, preferably apart by a distance of at most 5 mm, more preferably by a distance of at most 1 mm, and particularly preferably at a distance of at most 0.2 mm, from the supporter.

The present invention also provides a heater unit for a wafer prober provided with the wafer holder of the present invention described above, as well as a wafer prober mounting the heater unit.

The heater unit for the wafer prober provided with the wafer holder of the present invention and the wafer prober provided with the heater unit as described above can minimize the influence of noise, and therefore, highly accurate measurement is possible even by probing at a high frequency.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view schematically showing a wafer holder 1 as a first preferred example used in the present invention.

FIG. 2 is a cross-sectional view schematically showing a heater body 6 as a preferred example used in the present invention.

FIG. 3 is a top view schematically showing an example of a supporter 16 suitably used in the present invention.

FIG. 4 is a top view schematically showing another example of a supporter 21 suitably used in the present invention.

FIG. 5 is a top view schematically showing another example of a supporter 26 suitably used in the present invention.

FIG. 6 is a cross-sectional view schematically showing a wafer holder 31 as a second preferred example of the present invention.

FIG. 7 shows, partially in enlargement, a contact portion between a chuck top 2 and a circular tube portion of a supporter 4, of wafer holder 1 of the example shown in FIG. 1.

FIG. 8 is a cross-sectional view schematically showing a wafer holder 41 as a third preferred example of the present invention.

FIG. 9 is a cross-sectional view schematically showing a wafer holder 51 as a fourth preferred example of the present invention.

FIG. 10 is a cross-sectional view schematically showing a wafer holder 61 as a fifth preferred example of the present invention.

FIG. 11 is a cross-sectional view schematically showing a wafer holder 71 as a sixth preferred example of the present invention.

FIG. 12 is a cross-sectional view schematically showing a wafer holder 81 as a seventh preferred example of the present invention.

### DESCRIPTION OF THE PREFERRED EMBODIMENTS

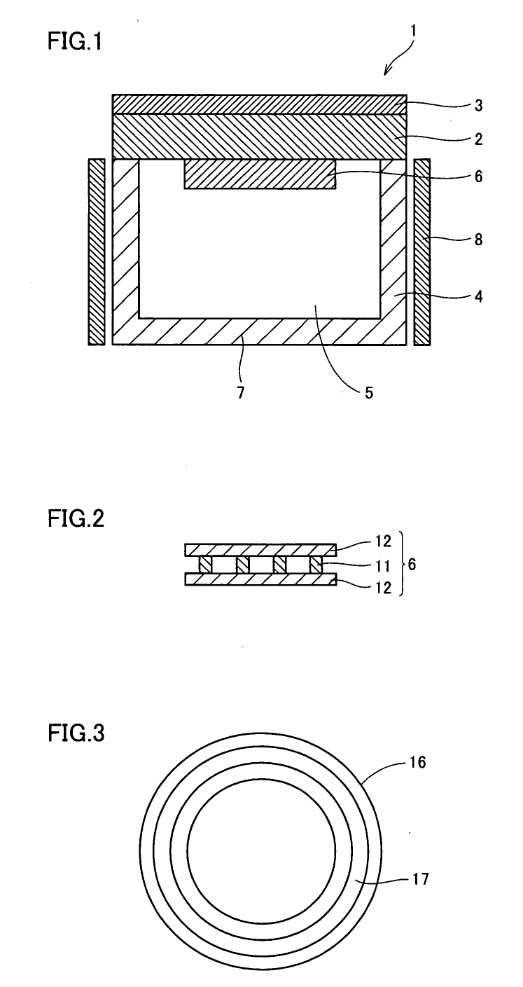

FIG. 1 is a cross-sectional view schematically showing a wafer holder 1 as a first preferred example of the present invention. Wafer holder 1 in accordance with the present invention basically includes a chuck top 2 for mounting a wafer, and a supporter 4 supporting chuck top 2. Typically, on chuck top 2, a chuck top conductive layer 3 such as shown in FIG. 1 is formed. In the example shown in FIG. 1, by way of example, a supporter 4 of a hollow cylindrical shape (hollow cylindrical shape with a bottom) having a bottom wall 7 on one side and opened at the other side is used. Supporter 4 as such is positioned with the opening side facing upward, and chuck top 2 is arranged to close the opening. In wafer holder 1 in accordance with the present invention, a heater body 6 is provided on chuck top 2. In the example shown in FIG. 1, heater body 6 is attached to a lower surface of chuck top 2 such that the body is housed in a space 5 of supporter 4. Further, supporter 4 is mounted on a driving system (not shown) for moving the wafer holder as a whole.

The wafer holder of the present invention is characterized in that at least a part of the supporter is covered with a metal member. In the wafer holder of the present invention, at least a part of the supporter is covered with a metal member, whereby the noise generated from the heater body is absorbed by the metal member, and the influence to proving can be prevented. FIG. 1 shows an example in which along the outer circumference of supporter 4, a metal member 8 is provided to cover entire side surface (outer circumferential surface) of supporter 4. Though metal member 8 used in the present invention is not specifically limited, use of deformable foil is preferred to attach the metal member uniformly over the supporter.

It is preferred that metal member 8 of wafer holder 1 in accordance with the present invention covers supporter 4 with a distance to supporter 4 made as small as possible. In wafer holder 1 of the present invention, the distance between metal member 8 and supporter 4 is preferably at most 5 mm. When the distance between metal member 8 and supporter 4 exceeds 5 mm, leakage of electromagnetic wave as the noise from the gap between supporter 4 and metal member 8 increases, and the effect of noise cut-down tends to decrease. The distance between metal member 8 and supporter 4 mentioned above refers to an average value of distances between supporter 4 and metal member 8 measured at arbitrary 8 points.

From the viewpoint of further enhancing the effect of noise absorption, it is preferred that the distance between metal member 8 and supporter 4 is at most 1 mm. Further, it is particularly preferred that the distance between metal member 8 and supporter 4 is at most 0.2 mm, as it becomes possible to minimize the influence of noise from the heater body as regards high-frequency characteristics of the wafer.

Though the method of providing metal member 8 is not specifically limited, when foil is used as metal member 8, a method may be possible as an example, in which a female screw is formed in the supporter, and the metal foil having a through hole formed therein is fixed by a conductive screw. In this method, however, the metal foil sags between one screw portion and another, and hence the sag must be made as small as possible. For this purpose, it is necessary to increase positional accuracy between the positions of female screws formed in the supporter and holes formed in the metal foil, and to make as small as possible the gap between the hole and the shape of the conductive screw to be inserted.

When foil is used as metal member 8, metal member 8 may be attached to supporter 4 by using an adhesive such as resin. In that case, it is necessary to make a clearance between supporter 4 and metal member 8 as small as possible for attachment. At the time of attaching metal member 8 on supporter 4 using an adhesive, the adhesive should be applied to supporter 4 or metal member 8 uniformly with the thickness of adhesive made as thin as possible, and metal member 8 should be put into shape before adhesion.

As to the position of arranging metal member 8, it is preferred to arrange at a portion as close as possible to heater body 6 and chuck top 2. When the position of arrangement is far from the position of heater body 6, the effect of noise cut-down degrades accordingly, and hence, it is not preferable. Arrangement of a ring-shaped metal member 8 on the entire outer circumferential surface of supporter 4 as shown in FIG. 1 is suitable, as the effect of noise cut-down is enhanced. Further, bottom wall 7 of supporter 4 may also be covered with metal member 8 (not shown), whereby noise leakage from supporter 4 can significantly be reduced.

Though the material for metal member 8 used in the present invention is not specifically limited, a metal such as stainless steel, chromium, nickel, molybdenum, or tungsten is suitable considering cost, durability and the like. The material for the conductive screw used for screw-fixing metal member 8 is not specifically limited, either, and other than the same material as the metal member 8, use of a metal such as Kovar is also possible.

Though the thickness of metal member 8 used in the present invention is not specifically limited, it is preferably at least 10 μm, considering cost and convenience in handling. When metal member 8 having the thickness smaller than 10 μm is used, it is possible that the metal member crinkles partially and the noise leaks from that portion. If attachment on supporter 4 is possible keeping the prescribed distance mentioned above, however, metal member 8 having the thickness smaller than 10 μm may be used without any particular problem.

Though an example in which metal member 8 covers the outer circumferential surface of supporter 4 is shown in FIG. 1, the metal member may cover the inner circumferential surface of the supporter.

In the example shown in FIG. 1, supporter 4 having a space 5 therein is used, and provision of such a space 5 enhances the effect of heat insulation between chuck top 2 and supporter 4. The shape of space 5 is not specifically limited, and it may have a shape that suppresses as much as possible the amount of transfer of heat generated at chuck top 2 or cold air to the supporter. Supporter 4 of wafer holder 1 in accordance with the present invention is preferably adopted to have a hollow cylindrical shape with a bottom as shown in FIG. 1, as contact area between chuck top 2 and supporter 4 can be made small and space 5 can be formed easily. Because space 5 as such is formed, what exists between chuck top 2 and supporter 4 is mostly an air layer, and hence, an efficient heat insulating structure is provided.

Wafer holder 1 in accordance with the present invention is formed with heater body 6 provided on chuck top 2. This is because it is often necessary in recent semiconductor probing to heat the semiconductor wafer to a temperature of 100 to 200° C. Therefore, if transfer of heat of heater body 6 heating the chuck top to supporter 4 could not be prevented, the heat would be transferred to the driving system provided at a lower portion of wafer prober supporter, resulting in variation in mechanical accuracy because of difference in thermal expansion coefficient among various components, and causing significant degradation in flatness and parallelism of the upper surface of the chuck top (wafer-mounting surface). However, when wafer holder 1 of the present invention is implemented, for example, by a structure such as shown in FIG. 1, flatness and parallelism would not significantly be degraded, as the structure has heat insulating effect as described above. Further, the structure such as shown in FIG. 1 is hollow, and therefore, the weight can be reduced as compared with a supporter having a solid cylindrical supporter.

FIG. 2 is a cross-sectional view schematically showing heater body 6 as a preferred example used in the present invention. As heater body 6 used in the present invention, one having a simple structure having a resistance heater body 11 sandwiched between insulators 12 as shown in FIG. 2 may preferably be used.

As resistance heater body 11, metal material may be used. By way of example, foil formed of nickel, stainless steel, silver, tungsten, molybdenum, chromium, nichrome and an alloy of these metals may preferably be used. Among these, a resistance heater body formed of stainless steel or nichrome is preferably used. Stainless steel or nichrome allows formation of a circuit pattern of resistance heater body with relatively high precision by a method such as etching, when it is processed to the shape of the heater body. Further, it is preferred because it is inexpensive, and is oxidation resistant and withstands use for a long period of time even when the. temperature of use is high.

Insulator 12 sandwiching resistance heater body 11 is not specifically limited, and any heat-resistant insulator may be used. By way of example, mica, silicone resin, epoxy resin, phenol resin or the like may be used. When insulator 12 is resin, filler may be dispersed in the resin, in order to increase thermal conductivity of insulator 12. Filler material is not specifically limited, provided that it does not have reactivity to the resin, and a substance such as boron nitride, aluminum nitride, alumina, silica or the like may be available.

Heater body 6 may be fixed on chuck top 2 by a mechanical method, for example, by fixing with a screw. Alternatively, heater body 6 may be provided by forming an insulating layer by thermal spraying or screen printing on a surface opposite to the wafer-mounting surface of chuck top 2, and forming a conductive layer in a prescribed pattern thereon by screen printing or vapor deposition.

Further, supporter 4 of wafer holder 1 in accordance with the present invention preferably has Young's modulus of at least 200 GPa. When Young's modulus of supporter 4 is smaller than 200 GPa, the bottom portion cannot be made thin, and therefore, sufficient volume of the space cannot be attained and the effect of heat insulation cannot be expected. Further, the space for mounting a cooling module, which will be described later, cannot be secured. More preferable Young's modulus of supporter 4 is at least 300 GPa. Use of a material having Young's modulus of at least 300 GPa is particularly preferred, as deformation of supporter 4 can be suppressed significantly and hence supporter 4 can further be reduced in size and weight. Young's modulus of supporter 4 mentioned above refers to a value measured by a method such as pulse method or flexural resonance method.

Further, supporter 4 of wafer holder 1 in accordance with the present invention preferably has thermal conductivity of at most 40 W/mK. When thermal conductivity of supporter 4 exceeds 40 W/mK, heat applied to chuck top 2 is easily transferred to the supporter, possibly affecting accuracy of the driving system. Recently, a temperature as high as 150° C. is required at the time of probing, and therefore, it is particularly preferred that the supporter has thermal conductivity of at most 10 W/mK. More preferably thermal conductivity is at most 5 W/mK. With the thermal conductivity of this range, amount of heat transfer from the supporter to the driving system decreases significantly. The thermal conductivity of supporter 4 described above refers to a value measured by a method such as laser flash method, using palletized samples.

Specific materials of supporter 4 having Young's modulus and thermal conductivity as described above include, by way of example, mullite or alumina, and a composite of mullite and alumina (mullite-alumina composite). Mullite is preferred in that it has low thermal conductivity and attains high heat insulating effect, and alumina is preferred in that it has high Young's modulus and high rigidity. Mullite-alumina composite is generally preferable, as it has lower thermal conductivity than alumina and higher Young's modulus than mullite.

When supporter 4 of hollow cylindrical shape with a bottom is used as in the example shown in FIG. 1, the thickness of cylindrical portion of supporter 4 is preferably at most 20 mm, though it is not specifically limited. When the thickness exceeds 20 mm, the amount of thermal transfer from chuck top 2 to supporter 4 might possibly increase. From the viewpoint of reducing the amount of heat transfer from chuck top 2 to supporter 4, said thickness should preferably be at most 10 mm. When said thickness is smaller than 1 mm, the hollow cylindrical portion of the supporter might possibly be deformed or damaged by the pressure when the probe card is pressed onto the semiconductor wafer. Particularly preferable range of said thickness is 10 to 15 mm. Further, from the viewpoint of balance between the strength and heat insulating characteristic of the supporter, the thickness of that portion of the hollow cylindrical portion which is in contact with chuck top 2 should preferably be in the range of 2 to 5 mm.

Further, when supporter 4 of hollow cylindrical shape with a bottom as shown in FIG. 1 is used, the height of hollow cylindrical portion is preferably at least 10 mm, though it is not specifically limited. At the time of inspection of the semiconductor wafer, the pressure from the probe card is applied to chuck top 2 and further propagated to supporter 4, and if the height of said hollow cylindrical portion is lower than 10 mm, bottom wall 7 of supporter 4 would deflect, possibly degrading flatness of chuck top 2.

When supporter 4 of hollow cylindrical shape with a bottom is used as in the example shown in FIG. 1, the thickness of bottom wall 7 of supporter 4 is preferably at least 10 mm, though it is not specifically limited, either. As described above, at the time of inspection of the semiconductor wafer, the pressure from the probe card is applied to chuck top 2 and further propagated to supporter 4, and if the thickness of said bottom wall 7 is smaller than 10 mm, bottom wall 7 of supporter 4 would deflect, possibly degrading flatness of chuck top 2. More preferably, the thickness of bottom wall 7 of supporter 4 is in the range of 10 to 35 mm. Thickness of said bottom wall 7 smaller than 35 mm is suitable as it allows size reduction.

Though an example in which supporter 4 having the hollow cylindrical shape with a bottom formed integrally is shown in FIG. 1, the circumferential wall (hollow cylinder portion) and the bottom wall forming the supporter may be formed as separate bodies. In that case, there is formed an interface between the circumferential wall and the bottom wall of the supporter, and it is preferred as the interface serves as a heat resistant layer and once stops the heat transferred from the chuck top to the supporter and temperature increase of bottom wall 7 is suppressed.

In the wafer holder in accordance with the present invention, a support surface of the supporter supporting the chuck top should preferably have a heat-insulating structure. The heat-insulating structure may be made by forming a notch in the supporter to reduce contact area between the chuck top and the supporter. It is also possible to form the heat-insulating structure by forming a notch in the chuck top. In that case, it is necessary that the chuck top has Young's modulus of at least 250 GPa. Specifically, as the pressure of probe card is applied to the chuck top, the amount of deformation would inevitably increase if a notch is formed and the material thereof has low Young's modulus. Large amount of deformation of the chuck top possibly leads to damage to the wafer or damage to the chuck top itself. Formation of the notch in the supporter is preferred, because such a problem can be avoided.

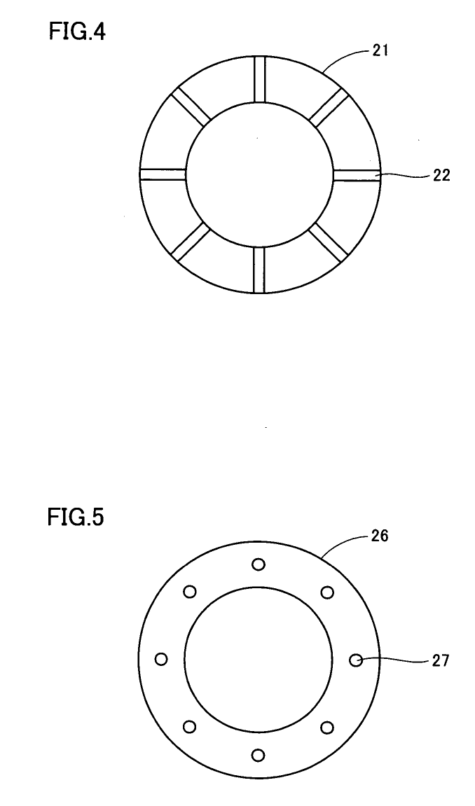

FIG. 3 is a top view schematically showing an example of a supporter 16 suitably used in the present invention. FIG. 4 is a top view schematically showing another example of a supporter 21 suitably used in the present invention. When a notch is formed in the supporter, a notch 17 as a circle concentric with the circle at the upper surface of the hollow cylindrical portion of supporter 16 may be formed at the upper surface of supporter 16, as represented by the example shown in FIG. 3. Alternatively, as in the example shown in FIG. 4, notches 22 may be formed in a radial pattern, at the upper surface of supporter 21. The shape of the heat-insulating structure is not specifically limited, as long as the shape is symmetrical. If the heat-insulating structure has asymmetrical shape, it becomes impossible to uniformly distribute the pressure applied on the chuck top, possibly causing deformation of or damage to the chuck top.

FIG. 5 is a top view schematically showing another example of a supporter 26 suitably used in the present invention. In the present invention, the heat-insulating structure may be formed by providing a plurality of pillar members 27 on the upper surface of supporter 26, as shown in FIG. 5. Here, at least 8 pillar members 27 should preferably be formed at an approximately uniform arrangement in a circle concentric with the circle at the upper surface of supporter 26. Particularly, the semiconductor wafers come to have larger size of 8 to 12 inches recently, and therefore, if the number is smaller, the distance between each pillar member becomes long, and when pins of the probe card are pressed to the semiconductor wafer mounted on the chuck top, deflection is likely between the pillar members.

When pillar member 27 is provided on the upper surface of supporter 26, pillar member 27 may be formed integral with supporter 26, or may be formed as separate bodies. Assuming that the contact area between the pillar member and the chuck top is the same as when formed integrally, when pillar member 27 is formed separate from supporter 26, two interfaces can be formed, that is, between chuck top 2 and pillar member 27 and between pillar member 27 and supporter 26. These interfaces can serve as the heat resistant layers, and hence, this approach is preferred. Specifically, when the pillar member and the supporter are formed as separate bodies, the number of heat resistant layers is twice as much as when they are formed integrally, and therefore, the heat generated at the chuck top can effectively be insulted.

When the pillar member is formed on the upper surface of the supporter, the shape of the pillar member is not specifically limited, and it may be a circular pillar as shown in the example of FIG. 5, or it may be a triangle pole, a quadrangular pole, a pipe or may have any other polygonal shape. No matter in what shape the member is formed, provision of the pillar member attains the effect that the heat from the chuck top to the supporter is intercepted.

Though the material for the pillar member is not specifically limited, it is preferred that a material having thermal conductivity of at most 30 W/mK is used. If a material having the thermal conductivity exceeding 30 W/mK is used for forming the pillar member, the heat insulating effect would possibly be weakened. Materials having such thermal conductivity include, by way of example, Si₃N₄, mullite, mullite-alumina composite, steatite, cordierite, stainless steel, glass (fiber), heat resistant resin such as polyimide, epoxy or phenol, and a composite thereof The thermal conductivity of the pillar member may be measured by the similar method as described above in connection with the thermal conductivity of the supporter.

In the wafer holder in accordance with the present invention, surface roughness Ra at a contact portion between the supporter and the chuck top or the pillar member is preferably at least 0.1 μm. If the surface roughness is smaller than 0.1 μm, contact area between the supporter and the chuck top or the pillar member increases and the gap between the two becomes relatively small, so that the amount of heat transfer would be increased than when the surface roughness Ra is larger than 0.1 μm. There is no specific upper limit for the surface roughness Ra. It is noted, however, that if the surface roughness is higher than 5 μm, the cost for surface processing possibly increases. As for the method of realizing surface roughness Ra of at least 0.1 μm, polishing process or sand blasting may be performed. In that case, however, conditions for polishing or sand blasting must be optimized to maintain surface roughness Ra of at least 0.1 μm.

Further, it is preferred that the bottom wall of the supporter has the surface roughness Ra of at least 0.1 μm. Similar to the above, when the surface roughness Ra of the bottom wall of the supporter is rough, the amount of heat transfer to the driving system can be reduced. When the bottom wall and the hollow cylindrical portion of said supporter are formed as separate bodies, surface roughness Ra of at least one of these at the contact portion should preferably be at least 0.1 μm. If the surface roughness Ra is smaller than this, the effect of heat insulation from the hollow cylindrical portion to the bottom wall is small. Further, the surface roughness Ra of the contact surface between said pillar member with the supporter and of the contact surface with the chuck top should also be at least 0.1 μm. By increasing the surface roughness Ra of the pillar member, again the heat transfer to the supporter can be reduced.

As described above, by forming an interface between each member and by making the surface roughness Ra of the interface equal to or larger than 0.1 μm, the amount of heat transfer to the bottom portion of the supporter can be reduced, and as a result, the amount of power supply to the heater body can also be reduced.

Perpendicularity of the contact surface between the hollow cylindrical portion of said supporter and the chuck top or the contact surface between the pillar member and the chuck top should preferably be at most 10 mm, with the measured length converted to 100 mm. For instance, with perpendicularity exceeding 10 mm, it is possible that the hollow cylindrical portion itself deforms when the pressure from the chuck top is applied to the hollow cylindrical portion of the supporter.

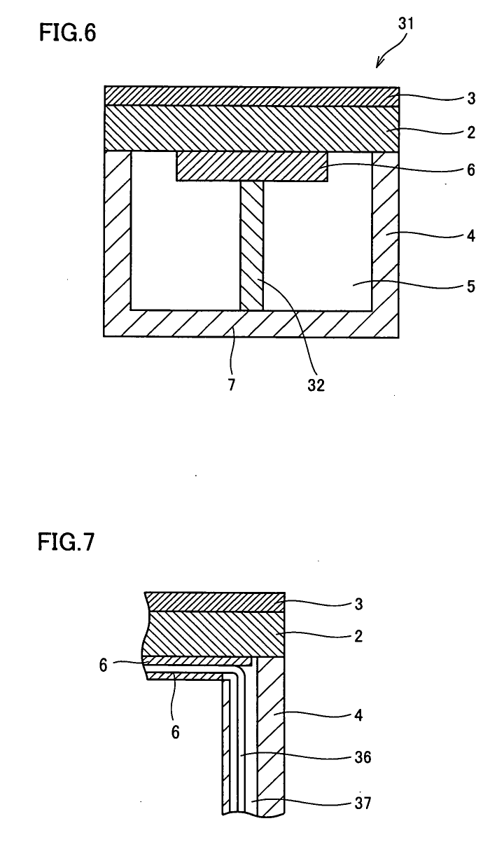

FIG. 6 is a cross-sectional view schematically showing a wafer holder 31 as a second preferred example of the present invention. Wafer holder 31 of the example shown in FIG. 6 has the same structure as that of wafer holder 1 of the example shown in FIG. 1 except for some points, and portions of the same structure are denoted by the same reference characters and description thereof will not be repeated. In the example shown in FIG. 6, the metal member is not shown.

Wafer holder 31 of the example shown in FIG. 6 has a support rod 32 provided near the central portion of supporter 4. By providing such a support rod 32, it becomes possible to suppress deformation of chuck top 2 when the probe card is pressed onto chuck top 2. Here, preferably, the material for support rod is the same as that of supporter 4. When chuck top 2 is heated, supporter 4 and support rod 32 receive heat from heater body 6 and thermally expand. If supporter 4 and support rod 32 were formed of different materials, chuck top 2 would be more susceptible to deformation because of the difference in thermal expansion coefficient between supporter 4 and support rod 32.

Though the size of support rod 32 is not specifically limited, its cross sectional area should preferably be at least 0.1 cm². When the cross sectional area of support rod 32 is smaller than 0.1 cm², the supporting effect by the support rod is insufficient and the support rod tends to deform, and therefore, it is not preferred. The cross sectional area of support rod 32 is preferably at most 100 cm². When the cross sectional area of support rod 32 exceeds 100 cm², the size of a cooling module to be inserted to the hollow cylindrical portion of the supporter becomes small as will be described later, possibly degrading the cooling effect.

The shape of support rod 32 is not specifically limited, and it may have the shape of a circular pillar, a triangle pole, a quadrangular pole, a pipe or the like. The method of fixing support rod 32 on supporter 4 is not specifically limited, either. By way of example, methods such as brazing with an active metal, glass fixing, or screw fixing may be used. Among these methods, it is particularly preferred to have support rod 32 fixed by screw on supporter 4. Screw fixing facilitates attachment/detachment, and as heat treatment is not involved at the time of fixing, deformation of supporter 4 or support rod 32 by the heat treatment can be avoided.

In the wafer holder of the present invention, it is preferred to form an electromagnetic shield electrode layer (not shown) on the side of chuck top 2 of heater body 6. Such an electromagnetic shield electrode layer cuts off noise such as electromagnetic wave or electric field generated at heater body 6 that may influence probing of the semiconductor wafer, and serves to significantly decrease noise to the semiconductor wafer on the chuck top. Though the noise does not have much influence on the measurement of common electric characteristics, it has a particularly significant influence on the measurement of high-frequency characteristics of the semiconductor wafer. As the electromagnetic shield electrode layer, by way of example, metal foil may be inserted between heater body 6 and chuck top 2, and chuck top 2 and heater body must be insulated. Though the metal foil to be used here is not specifically limited, foil of stainless steel, nickel or aluminum is preferred, as heater body 6 is heated to the temperature of about 200° C.

In the wafer holder of the present invention, when the chuck top is an insulator and it is conductive to the chuck top conductive layer formed on the wafer-mounting surface of the chuck top, or when the chuck top is a conductor, in terms of an electric circuit, a capacitor comes to be formed between the chuck top itself and the electromagnetic shield layer, and the capacitor component may have an influence as noise at the time of probing the semiconductor wafer. Therefore, it is preferred in the wafer holder of the present invention to form an insulating layer (not shown) between the electromagnetic shield electrode layer and the chuck top. Formation of the insulating layer reduces the influence of noise mentioned above.

Further, it is preferred that the wafer holder in accordance with the present invention includes a guard electrode layer (not shown) between the chuck top and the electromagnetic shield electrode layer, with an insulating layer interposed. When electrically connected to the metal member provided to cover said supporter, the guard electrode layer can further reduce the noise that affects measurement of the high-frequency characteristics of the semiconductor wafer. Specifically, in the present invention, by covering the supporter as a whole including the heater body with a conductor, the influence of noise at the time of measuring the characteristics of the semiconductor wafer at a high frequency can be reduced. Further, by electrically connecting the guard electrode layer to said metal member, the influence of noise can further be reduced.

Here, it is preferred that the resistance value between the heater body and the electromagnetic shield electrode layer, between the electromagnetic shield electrode layer and the guard electrode layer, and between the guard electrode layer and the chuck top is at least 10⁷Ω. When said resistance value is smaller than 10⁷Ω, small current flows to the chuck top conductive layer because of the influence of heater body, which possibly becomes noise at the time of probing and affects probing. Setting the resistance value of the insulating layer to be at least 10⁷Ω is preferable as the small current can sufficiently be reduced not to affect proving. Recently, circuit patterns formed on semiconductor wafers have been miniaturized, and therefore, it is necessary to reduce such noise as much as possible. By setting the resistance value of the insulating layer to at least 10¹⁰Ω, a structure of higher reliability can be obtained.

Further, it is preferred that the dielectric constant of said insulating layer is at most 10. When the dielectric constant of the insulating layer exceeds 10, charges tend to be stored more easily at the chuck top, the guard electric layer and the electromagnetic shield layer sandwiching the insulating layer, which might possibly be a cause of noise generation. Particularly, the wafer circuits have been much miniaturized in these days as described above, it is necessary to reduce noise, and therefore, dielectric constant should preferably be at most 4 and more preferably at most 2. By setting small the dielectric constant of the insulating layer, the thickness of the insulating layer necessary for ensuring insulation resistance and capacitance can be made thinner, and hence, thermal resistance posed by the insulating layer can be reduced.

In the wafer holder of the present invention, when the chuck top is an insulator and it is conductive between the chuck top conductive layer and the guard electrode layer or it is conductive between the chuck top conductive layer and the electromagnetic shield electrode layer, or when the chuck top is a conductor, the capacitance between the chuck top itself and the guard electrode, and between the chuck top and the electromagnetic shield electrode layer should preferably be at most 5000 pF. When the capacitance exceeds 5000 pF, the influence of the insulating layer as a capacitor would be too large, possibly becoming noise at the time of probing. Considering the miniaturization of wafer circuits as described above, it is particularly preferred to have said capacitance of at most 1000 pF, as it enables good probing.

As described above, by controlling the resistance value, dielectric constant and capacitance of the insulating layer in the ranges as describe above, the noise having an influence at the time of probing can significantly be reduced.

When the insulating layer is formed, the thickness should preferably be at least 0.2 mm, though it is not limiting. In order to reduce the size of the device and to maintain good heat conduction from the heater body to the chuck top, the thickness of the insulating layer should be small. When the thickness of the insulating layer becomes smaller than 0.2 mm, however, defects in the insulating layer itself or problems in durability would be generated. It is preferred that the insulating layer has the thickness of at least 1 mm, because such a thickness prevents the problem of durability and ensures good heat conduction from the heater body. Though there is no specific upper limit of the thickness of the insulating layer, preferably it is at most 10 mm. When the thickness of the insulating layer exceeds 10 mm, though the noise cutting effect is good, the time of conduction of the heat generated by heater body to the chuck top and to the semiconductor wafer becomes too long, and hence, it becomes difficult to control the heating temperature. Though it depends on the conditions of probing, the thickness of the insulating layer up to 5 mm is preferred, as temperature control is relatively easy.

Though the thermal conductivity of the insulating layer is not specifically limited, it is preferably be at least 0.5 W/mK, in order to realize good heat conduction from the heater body as described above. Thermal conductivity of the insulating film of at least 1 W/mK is preferred, as heat conduction is improved. The thermal conductivity of the insulating layer refers to a value measured by the similar method as described with reference to the thermal conductivity of the supporter above.

Specific material for the insulating layer is not limited, provided that it satisfies the characteristics described above and has heat resistance sufficient to withstand the probing temperature, and possible example may be ceramics or resin. Of these, resin such as silicone resin or the resin having filler dispersed therein, and ceramics such as alumina, may preferably used. The filler dispersed in the resin serves to improve heat conduction of the silicone resin, and the material for the filler is. not specifically limited as long as it has no reactivity to the resin. By way of example, substances such as boron nitride, aluminum nitride, alumina and silica may be available.

In the wafer holder of the present invention, the size of the area on which the insulating layer is formed is preferably the same or larger than the size of each of the areas for forming said electromagnetic shield electrode layer, the guard electrode and the heater body. If the area for forming the insulating layer is smaller than each of the areas for forming said electromagnetic shield electrode layer, the guard electrode and the heater body, noise may possibly enter from a portion not covered with the insulating layer.

An example will be described in the following. Said insulating layer is formed, for example, by using silicone resin having boron nitride dispersed therein. The material has dielectric constant of 2. When the silicone resin with boron nitride dispersed is inserted as the insulating layer between said electromagnetic shield layer and the guard electrode layer and between the guard electrode layer and the chuck top, and the chuck top corresponds to a 12-inch wafer, it may be formed, for example, to have the diameter of 300 mm. At this time, when the thickness of the insulating layer is set to 0.25 mm, capacitance of 5000 pF can be attained. When the thickness is set to 1.25 or more, capacitance of 1000 pF or lower can be attained. Volume resistivity of the material is 9×10¹⁵ Ω·cm, and therefore, when the diameter is 300 mm and the thickness is made at least 0.8 mm, the resistance value of about 1×10¹²Ω can be attained. Further, as the material has thermal conductivity of about 5 W/mk and, though the thickness may be selected considering the conditions of probing, sufficient capacitance and sufficient resistance can be attained by setting the thickness to at least 1.25 mm.

FIG. 7 shows, partially in enlargement, a contact portion between chuck top 2 and the circular tube portion of supporter 4, of wafer holder 1 of the example shown in FIG. 1. As shown in FIG. 7, preferably, at a circular tube portion of supporter 4, a through hole 37 is formed to pass an electrode line 36 for feeding power to heater body 6 or an electrode line (not shown) of the electromagnetic shield. Such a structure facilitates handling of electrode line 36. Here, the position for forming through hole 37 is preferably close to an inner circumferential surface of the circular tube portion of supporter 4, as decrease in strength at the circular tube portion of supporter 4 can be minimized.

Further, when the chuck top warps by more than 30 μm in the wafer holder of the present invention, contact with a probe needle of the probe card may possibly be biased at the time of inspection, resulting in a contact failure. Similar contact failure would be possible if the parallelism between the surface of the chuck top conductive layer and the bottom surface of the supporter is 30 μm or larger. Said warp and parallelism should be smaller than 30 μm not only at a room temperature but also in the general temperature range of inspection of −70° C. to 200° C.

The chuck top conductive layer formed on the wafer-mounting surface of the chuck top has a function of a ground electrode and, in addition, functions of cutting off electromagnetic noise from the heater body, and protecting the chuck top from corrosive gas, acid, alkali chemical, organic solvent or water.

Possible methods of forming the chuck top conductive layer include a method in which a conductive paste is applied by screen printing and then fired, vapor deposition or sputtering, thermal spraying and plating. Among these methods, thermal spraying and plating are particularly preferred. These methods do not involve heat treatment at the time of forming the conductive layer, and therefore, warp of the chuck top caused by heat treatment can be avoided and the conductive layer can be formed at a low cost.

Particularly, a method of forming the chuck top conductive layer by forming a thermally sprayed film on the chuck top and then forming a plating film further thereon is preferred. The material thermally sprayed (aluminum, nickel or the like) forms some oxide, nitride or oxynitride at the time of thermal spraying, and such compound reacts to the chuck top surface, realizing firm contact. The thermally sprayed film, however, has low electric conductivity because it contains the compound mentioned above. In contrast, plating forms an almost pure metal film, and therefore, a conductive layer of superior electric conductivity can be formed. Contact strength with the chuck top surface, however, is not as high as that of the thermally sprayed film. The thermally sprayed film and the plating film both contain metal as the main component and, therefore, contact strength therebetween is high. Therefore, by forming the thermally sprayed film as a base and forming plating film thereon, a chuck top conductive layer having both high contact strength and high electric conductivity can be provided.

In the wafer holder of the present invention, the chuck top conductive layer preferably has the surface roughness Ra of at most 0.5 μm. When the surface roughness of the chuck top conductive layer exceeds 0.5 μm, the heat generated from a device having a high calorific value during inspection of the device could not be radiated from the chuck top, and the device might possibly be broken by the heat. The surface roughness Ra of said chuck top conductive layer should more preferably be at most 0.02 μm, as more efficient heat radiation becomes possible.

When the heater body is heated and probing is performed, for example, at 200° C., it is preferred that the temperature at a lower surface of the supporter is at most 100 ° C. When the temperature at the lower surface of the supporter exceeds 100° C., there would be a distortion generated in the driving system of the prober provided below the supporter because of a difference in thermal expansion coefficient, and the accuracy of the system would be deteriorated, resulting in problems such as positional deviation at the time of probing, warp, and biased contact of the probe derived from degradation in parallelism. Consequently, accurate evaluation of the device would be difficult. Further, when the measurement is to be done at a room temperature after temperature elevation to 200° C., it takes time to cool from 200° C. to the room temperature, and hence, throughput would be decreased.

Further, in the wafer holder of the present invention, Young's modulus of the chuck top should preferably be at least 250 GPa. If Young's modulus is smaller than 250 GPa, the chuck top would be significantly deformed when load is applied at the time of inspection, resulting in a contact failure and possibly causing damage to the wafer. Young's modulus of the chuck top should preferably be at least 250 GPa and more preferably at least 300 GPa, as the possibility of contact failure can further be reduced. Young's modulus of the chuck top can be measured by the similar method as that of measuring Young's modulus of the supporter described above.

In the wafer holder of the present invention, the chuck top preferably has thermal conductivity of at least 15 W/mK. When the thermal conductivity of the chuck top is lower than 15 W/mK, temperature uniformity of the wafer mounted on the chuck top would be deteriorated. When the thermal conductivity of the chuck top is not lower than 15 W/mK, thermal uniformity having no adverse influence on inspection can be attained. As a material having such thermal conductivity, alumina having 99.5% purity (thermal conductivity 30 W/mK) is available. It is particularly preferable that thermal conductivity of the chuck top is at least 170 W/mK. As a material having such thermal conductivity, aluminum nitride (170 W/mK) or an Si—SiC composite (170 W/mK˜220 W/mK) is available. With thermal conductivity of this range, a chuck top having superior thermal uniformity can be obtained. Thermal conductivity of said chuck top can be measured by the similar method as that of measuring thermal conductivity of the supporter described above.

In the wafer holder of the present invention, the chuck top preferably has the thickness of at least 5 mm. When the thickness of the chuck top is thinner than 5 mm, the chuck top would deflect because of the load applied at the time of probing, and flatness and parallelism of the chuck top upper surface would be degraded significantly. As a result, accurate inspection would become difficult because of contact failure of a probe pin, and further, the semiconductor wafer might be damaged. Therefore, the chuck top should preferably have the thickness of at least 5 mm and more preferably at least 7 mm.

Preferable material for forming the chuck top includes metal-ceramics composite, ceramics and metal. As the metal-ceramics composite, any of a composite of aluminum and silicon carbide, a composite of silicon and silicon carbide, and a composite of aluminum, silicon and silicon carbide is preferred. Among these, the composite of silicon and silicon carbide particularly has high Young's modulus and high thermal conductivity, and hence, it is very preferable.

Further, as these composite materials are conductive, they may be used as materials for the heater body. By way of example, the heater body may be formed by forming an insulating layer through a method of thermal spraying or screen printing on a surface opposite to the wafer-mounting surface of the chuck top, and by screen printing the conductive layer thereon using the composite material mentioned above, or by forming the conductive layer in a prescribed shape through a method such as vapor deposition.

Alternatively, metal foil of stainless steel, nickel, silver, molybdenum, tungsten, chromium and an alloy of these may be etched to form a prescribed pattern, to provide the heater body. In this method, insulation from the chuck top may be attained by the method similar to that described above, or an insulating sheet may be inserted between the chuck top and the heater body. This is preferable, as the insulating layer can be formed at considerably lower cost and in a simpler manner than the method described above. Resin available for this purpose includes, from the viewpoint of heat resistance, mica sheet, epoxy resin, polyimide resin, phenol resin and silicone resin. Among these, mica is particularly preferable, as it has superior heat resistance and electric insulation, allows easy processing and is inexpensive.

Use of ceramics as the material for the chuck top is advantageous in that formation of an insulating layer between the chuck top and the heater body is unnecessary. Among ceramics, alumina, aluminum nitride, silicon nitride, mullite, and a composite material of alumina and mullite are preferred as they have relatively high Young's modulus and hence, not much deformed by the load of the probe card. Of these, alumina is preferred as it can be used at a relatively low cost and it has high insulation characteristic at a high temperature. Generally, in order to lower sintering temperature of sintering alumina, an oxide of alkali-earth metal, silicon or the like is added. If the amount of addition is decreased and purity of alumina is increased, insulating characteristic can further be improved, though the cost increases. High insulating characteristic can be attained at the purity of 99.66%, and higher insulating characteristic can be attained at the purity of 99.9%. Specifically, when sintering an alumina substrate, generally, an oxide of alkali-earth metal, silicon or the like is added to lower the sintering temperature, and such additive degrades electric characteristics of pure alumina such as insulating characteristic at a high temperature. Therefore, alumina having the purity of at least 99.6% is preferred and at least 99.9% is more preferred.

Alternatively, a metal may be applied as the material for the chuck top. In that case, tungsten, molybdenum and an alloy of these having high Young's modulus may be used. Specific examples of the alloy are an alloy of tungsten and copper, and molybdenum and copper. These alloys can be produced by impregnating tungsten or molybdenum with copper. Similar to the ceramics-metal composite described above, such metal is a conductor, and therefore, by forming the chuck top conductor and forming the heater body directly applying the method described above, a chuck top for use is obtained.

In the wafer holder of the present invention, it is preferred that the chuck top deflects at most by 30 μm when a load of 3.1 MPa is applied to the chuck top. A large number of pins of the probe card for inspecting the semiconductor wafer press the semiconductor wafer on the chuck top, and therefore, the pressure also acts on the chuck top, and the chuck top deflects to no small extent. When the amount of deflection exceeds 30 μm, it becomes impossible to press the pins of the probe card uniformly onto the semiconductor wafer, and inspection of the semiconductor wafer might be failed. More preferably, the amount of deflection under pressure is at most 10 μm.

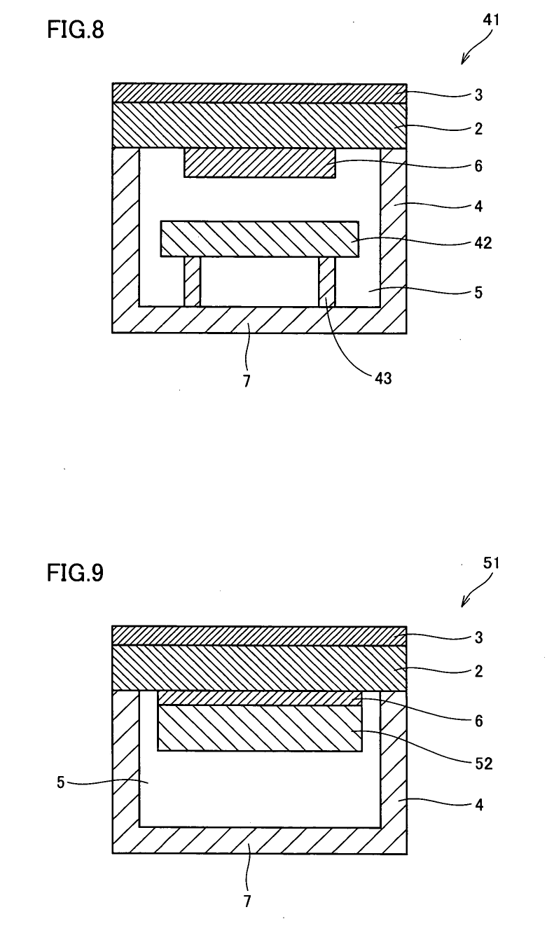

FIG. 8 is a cross-sectional view schematically showing a wafer holder 41 as a third preferred example of the present invention. Wafer holder 41 of the example shown in FIG. 8 has the same structure as that of wafer holder 1 of the example shown in FIG. 1 except for some points, and portions of the same structure are denoted by the same reference characters and description thereof will not be repeated. Wafer holder 41 of the example shown in FIG. 8 is characterized in that a cooling module 42 is provided in space 5 of supporter 4 having the circular tube portion. Provision of cooling module 42 is preferred, because, when it becomes necessary to cool chuck top 2, the heat can be removed and the chuck top 2 can be cooled rapidly, improving the throughput.

At the time of heating chuck top 2, if cooling module 42 can be separated from chuck top 2, highly efficient temperature elevation becomes possible. For this purpose, preferably, cooling module 42 is made movable. FIG. 8 shows an example in which cooling module 42 is provided on elevating means such as an air cylinder, realizing mobile cooling module 42. Cooling module 42 does not bear the load of probe card, and therefore, it is free from the problem of deformation caused by the load. Further, it is preferred as it attains higher cooling performance than air-cooling.

FIG. 9 is a cross-sectional view schematically showing a wafer holder 51 as a fourth preferred example of the present invention. Wafer holder 51 of the example shown in FIG. 9 has the same structure as that of wafer holder 41 of the example shown in FIG. 8 except for some points, and portions of the same structure are denoted by the same reference characters and description thereof will not be repeated. In the wafer holder of the present invention, when the cooling rate of the chuck top is of high importance, the cooling module may be fixed on the chuck top. FIG. 9 shows an example in which heater body 6 is provided on a side opposite to the wafer-mounting surface of chuck top 2, and a cooling module 52 is fixed on a lower surface of heater body 6.

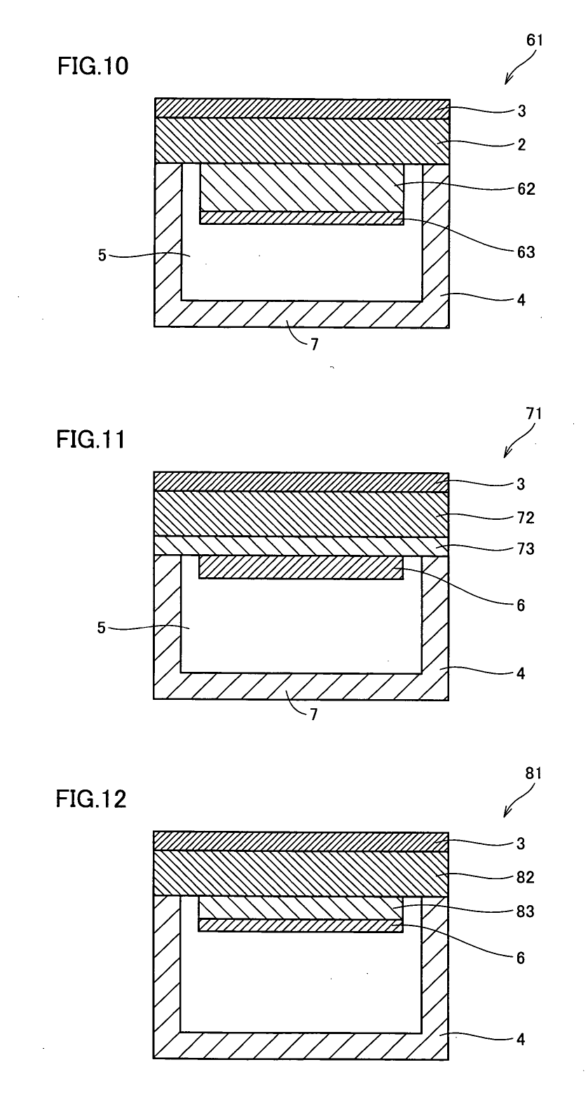

FIG. 10 is a cross-sectional view schematically showing a wafer holder 61 as a fifth preferred example of the present invention. Wafer holder 61 of the example shown in FIG. 10 has the same structure as that of wafer holder 41 of the example shown in FIG. 8 except for some points, and portions of the same structure are denoted by the same reference characters and description thereof will not be repeated. In the example shown in FIG. 10, a cooling module 62 is directly provided on a side opposite to the wafer-mounting surface of chuck top 2, and on a lower surface of cooling module 62, a heater body 63 similar to heater body 6 described above is fixed. Here, it is also possible to insert a deformable and heat-resistant soft material having high thermal conductivity (not shown) between the side opposite to the wafer-mounting surface of chuck top 2 and cooling module 62. By providing the soft material between chuck top 2 and cooling module 62 that can moderate warp or parallelism of the two, it becomes possible to enlarge the contact area, and the original cooling performance of the cooling module can more fully be exhibited, realizing higher cooling rate.

In any of the examples described above, the method of fixing the cooling module on the wafer holder of the present invention is not specifically limited, and it can be fixed mechanically, for example, by screw fixing or clamping. When the chuck top and the cooling module and the heater body are fixed by screws, three or more screws are preferred as tight contact between each of the members can be improved,. and six or more screws are more preferred.

Further, the cooling module may be provided in the space of the supporter, or the cooling module may be mounted on the supporter and the chuck top may be mounted thereon. No matter which method of mounting is adopted, cooling rate can be increased as compared with the movable example (FIG. 8), as the chuck top and the cooling module are firmly fixed. When the cooling module is mounted on the supporter, contact area between the cooling module and the chuck top increases, and therefore, the chuck top can be cooled in a shorter time.

When the cooling module fixed on the chuck top can be cooled by a coolant, it is preferred that the flow of coolant to the cooling module is stopped when the temperature of the chuck top is increased or when it is kept at a high temperature. In that case, the heat generated by the heater body is not removed by the coolant, and the heat does not escape to the outside of the system, whereby efficient temperature increase or maintenance of high temperature becomes possible. Naturally, the chuck top can be cooled efficiently by causing the coolant to flow again at the time of cooling.

Further, the chuck top and the cooling module may be formed integrally. In that case, materials for the chuck top and the cooling module is not specifically limited. However, as it is necessary to form a passage for the coolant flowing through the cooling module, it is preferred that the difference in thermal expansion coefficient between the chuck top and the cooling module is as small as possible. Naturally, it is preferred that the two are formed from the same material.

As for the material used here, ceramics or a composite of ceramics and metal described as the material for the chuck top above, may be used. Here, on the side of wafer-mounting surface of the chuck top, the chuck top conductive layer is formed, on the opposite surface, a flow passage for cooling is formed, and a substrate of the same material as the chuck top is provided integrally by, for example, brazing or glass fixing, whereby the wafer holder is fabricated. Further, the flow passage may be formed on the substrate side to be the cooling module, or flow passages may be formed on both sides. Integral formation using screws is also possible.

By forming the chuck top and the cooling module in an integrated manner as described above, the chuck top can more quickly be cooled than when the cooling module is fixed on the chuck top (FIGS. 9, 10).

FIG. 11 is a cross-sectional view schematically showing a wafer holder 71 as a sixth preferred example of the present invention. Wafer holder 71 of the example shown in FIG. 11 has the same structure as that of wafer holder 41 of the example shown in FIG. 8 except for some points, and portions of the same structure are denoted by the same reference characters and description thereof will not be repeated. Wafer holder 71 of the example shown in FIG. 11 includes chuck top 72 formed integrally with the module cooling plate as described above, and on the surface opposite to the wafer-mounting surface of chuck top 72, a substrate 73 for preventing deformation of the chuck top is provided.

When the chuck top and the cooling module are formed integrally as described above, a metal may be used as the material for the chuck top. As compared with ceramics or a composite of ceramics and metal described above, metal allows easier processing and is inexpensive, and therefore, it is easier to form the flow passage of the coolant. When the chuck top integral with the cooling module is formed of metal, however, it may possibly deflect because of the pressure applied at the time of probing. By providing substrate 73 for preventing deformation of the chuck top, such deflection can be prevented. Deflection can be prevented by the provision. As the substrate for preventing deformation of the chuck top, a substrate having Young's modulus of at least 250 GPa is preferably used.

FIG. 12 is a cross-sectional view schematically showing a wafer holder 81 as a seventh preferred example of the present invention. Wafer holder 81 of the example shown in FIG. 12 has the same structure as that of wafer holder 71 of the example shown in FIG. 11 except for some points, and portions of the same structure are denoted by the same reference characters and description thereof will not be repeated. FIG. 12 shows an example including a chuck top 82 formed integrally with the module cooling plate as described above, with a substrate 83 for preventing deformation of the chuck top provided on a side opposite to the wafer-mounting surface of chuck top 82, to be accommodated within the space of the supporter.

When the substrate for preventing deformation of the chuck top is provided, the substrate for preventing deformation of the chuck top may be formed integral with the chuck top. In that case, the portion of substrate for preventing deformation of the chuck top may be accommodated in the space of the supporter as shown in FIG. 12. The substrate for preventing deformation of the chuck top may be fixed on the chuck top by a mechanical method such as screw fixing or the method of brazing or glass fixing as described above, whereby it can be formed integrally with the chuck top. Here, as in the example (FIG. 10) in which the cooling module is fixed on the chuck top, it is preferred to stop the flow of coolant when the temperature of the chuck top is increased or when it is kept at a high temperature, and to cause the flow of coolant at the time of cooling, as more efficient heating and cooling become possible.

When the material for the chuck top is a metal of which surface is susceptible to oxidation or alteration, or a metal not having high electric conductivity, a chuck top conductive layer may be again formed on the wafer-mounting surface of the chuck top. The chuck top conductive layer may be formed by providing oxidation resistant plating such as nickel or by a combination with thermal spraying as described above, and then by polishing the surface of the wafer-mounting surface.

Even in such structures as shown in FIGS. 8 to 12, it is possible to appropriately form the electromagnetic shield electrode layer or the guard electrode layer described above, as needed. In that case, the insulated heater body is covered with the metal described above, a guard electrode layer is formed with an insulating layer interposed, and an insulating layer is formed between the guard electrode layer and the chuck top. The, the substrate for preventing deformation of the chuck top may be formed integrally on the chuck top.

When the cooling module is formed integrally with the chuck top, it may be provided such that the cooling module portion is accommodated in the space of the supporter, or it may be provided such that the opening of the supporter is closed by the cooling module portion as in the case where the chuck top and the cooling module are fixed by screws.

Though the material for the cooling module is not specifically limited, aluminum, copper or an alloy thereof is preferred as it has high thermal conductivity and capable of quickly removing heat from the chuck top. Use of metal material such as stainless steel, magnesium alloy, nickel or the like is also possible. To add oxidation resistance to the cooling module, an oxidation resistant metal film of nickel, gold or silver may be formed by plating or thermal spraying.

As the material for cooling module, ceramics may be used. Among the ceramics, aluminum nitride and silicon carbide are preferred, as they have high thermal conductivity and capable of quickly removing heat from the chuck top. Further, silicon nitride and aluminum oxynitride are preferred, as they have high mechanical strength and superior durability. Oxide ceramics such as alumina, cordierite and steatite are preferred as they are relatively inexpensive. As described above, the material for the cooling module may be arbitrarily selected in consideration of intended use, cost and the like. Of these materials, nickel-plated aluminum and nickel-plated copper are particularly preferred, as they have superior oxidation resistance and high thermal conductivity, and are relatively inexpensive.

It is preferred to provide a coolant flowing in the cooling module. By the flow of coolant, the heat transferred from the chuck top to the cooling module can quickly be removed from the cooling module, and the cooling rate of the chuck top can be improved.

As the method of forming the passage for the coolant flow, two plates are prepared, for example, and the passage is formed by machine processing on one of the plates. In order to improve corrosion resistance and oxidation resistance, entire surfaces of the two plates are nickel-plated, and thereafter, the two plates are joined by means of screws or welding. At this time, an O-ring or the like may preferably be inserted around the passage, to prevent leakage of the coolant.

Alternatively, two copper plates (oxygen-free copper) are prepared, and. the passage through which water flows is. formed by machine processing or the like on one of the copper plates. The other copper plate and a pipe formed of stainless steel at an inlet of the coolant are simultaneously joined by brazing. The entire surface of the joined cooling plate is nickel-plated, so as to improve corrosion resistance and oxidation resistance.

As another approach, a pipe through which the coolant flows may be attached to a cooling plate such as an aluminum plate or copper plate, to provide the cooling module. In this case, by forming a counter-sunk trench having a shape close to the cross-sectional shape of the pipe to realize close contact with the pipe, cooling efficiency can further be increased. Further, in order to improve tight contact between the cooling pipe and the cooling plate, thermally conductive resin, ceramics or the like may be inserted as an intervening layer.

As another approach, a pipe allowing passage of the coolant may be fixed on aluminum or copper, to provide the cooling module. In this case, in order to ensure contact area between the pipe and aluminum or copper, the metal plate of aluminum or copper may be processed to have a trench of approximately the same shape as the pipe, or a deformable substance such as resin may be inserted between the metal plate and the pipe. Alternatively, the cross-sectional shape of the pipe may be made partially flat, and that portion may be fixed on the metal plate. As to the method of fixing the metal plate and the pipe, screw fixing using a metal band, welding or brazing may be available.

Types of the coolant caused to flow through the cooling module may be liquid such as water, Fluorinert or Galden, or gas such as nitrogen, air or helium. The coolant is not specifically limited, and one suitable for the intended use may be used.

The wafer holder in accordance with the present invention may be suitably used for heating and inspecting an object of processing such as a wafer. Further, the wafer holder in accordance with the present invention may be suitably used as a heater unit for a wafer prober. The present invention also provides such a heater unit for the wafer prober.

Further, the present invention also provides a wafer prober provided with the heater unit for the wafer prober described above. In the wafer prober in accordance with the present invention, conventionally known appropriate structures may be adopted without any specific limitation, except for the heater unit of the present invention described above. The wafer prober of the present invention is suitable as the characteristics of the wafer holder in accordance with the present invention, that is, high rigidity and high thermal conductivity, can be utilized particularly well. The wafer holder in accordance with the present invention is also suitably applicable to a handler apparatus or a tester apparatus, other than the wafer prober.

### EXAMPLES

### Example 1

Wafer holder 1 as an example shown in FIG. 1 was fabricated in the following manner.

A substrate of silicon and silicon carbide composite (Si—SiC substrate) and an alumina substrate having the purity of 99.5%, diameter of 310 mm and thickness of 15 mm were prepared. On wafer-mounting surfaces of these substrates, concentric circular trenches for vacuum chucking a semiconductor wafer and through holes were formed, and respective wafer-mounting surfaces were nickel-plated, whereby chuck top conductive layers were formed. Thereafter, the chuck top conductive layer was polished, the overall warp is adjusted to 10 μm, the surfaces were finished to have surface roughness Ra of 0.02 μm, and thus, two types of chuck tops using the alumina substrate and the Si—SiC substrate were formed.

Next, two mullite-alumina composite bodies having the diameter of 310 mm and thickness of 40 mm were prepared as supporters. The supporters are counter-bored to have an inner diameter of 295 mm and the depth of 20 mm. On each chuck top, stainless steel foil insulated with a silicone resin sheet is attached as the electromagnetic shield electrode layer, and further, a heater body sandwiched by a silicone resin sheet was attached. The heater body was prepared by etching stainless steel foil to a prescribed pattern. Further, a through hole for connecting an electrode feeding power to the heater was formed in the supporter.

On a side surface and a bottom surface of the supporter, metal foil was attached entirely, as the metal member. As the metal foil, stainless steel foil having the thickness of 50 μm was used. The stainless steel foil was fixed on the side surface of the supporter at 16 points, that is, 8 points each on upper and lower portions of the supporter at an equal interval, using screws formed of Kovar. By varying the diameter of the hole for putting in the screw formed in the stainless steel foil, the distance between the supporter and the metal foil was adjusted as shown in Table 1. The distance between the supporter and the metal foil was measured at 8 points intermediate between one screw and another, from the side of chuck top mounting surface. A wafer holder not having metal foil was also fabricated (which corresponds to supporter-metal foil interval of “none” in Table 1).

Further, at the bottom of the supporter, stainless steel foil having the diameter of 311 mm and the thickness of 50 μm was provided, the chuck top having the heater body and the electromagnetic shield electrode layer attached was placed on the supporter, and thus the wafer holder for a wafer prober having the structure shown in FIG. 1 was obtained.

The heater body of each of the wafer holders described above was electrically conducted to heat the semiconductor wafer to 200° C., and the wafer probing at a high frequency was conducted successively. The results are as shown in Table 1. The results were the same no matter which of alumina substrate and the Si—SiC substrate was used.

In Table 1, A represents that probing was done while the noise was hardly observed. B represents that though some noise was observed, it did not have any influence to probing. C represents that measurement was sometimes influenced by the noise. D represents that measurement was almost impossible because of the influence of noise.

TABLE 1

| | Distance between supporter - metal | |
|---|---|---|
| | member (mm) | Result of probing |
| 1 | 0.05 | A |
| 2 | 0.1 | A |
| 3 | 0.2 | A |
| 4 | 0.5 | B |
| 5 | 0.8 | B |
| 6 | 1 | B |
| 7 | 2 | C |
| 8 | 5 | C |
| 9 | 8 | D |
| 10 | No metal member | D |

No matter which of the alumina substrate and the Si—SiC substrate was formed, measurement at a high frequency was made possible when the distance between the supporter and the metal foil was set to 5 mm or smaller. When the distance between the supporter and the metal foil was set to 1 mm or smaller, the influence of noise can be reduced, and when the distance was set to 0.2 mm or smaller, good probing result was attained.

### Example 2

Chuck tops and supporters similar to those of Example 1 were prepared, and stainless steel foil similar to that of Example 1 was prepared as the metal member. The width of attachment of the stainless steel foil attached on the side surface, from the upper portion of the supporter, was varied and the influence thereof was confirmed as in Example 1. Here, the distance between the stainless steel and the supporter was each set to 0.1 mm. As in Example 1, the results were the same regardless of the chuck top material. Meanings of signs A, B, C and D representing the evaluation results in Table 2 are the same as those of Example 1.

TABLE 2

| | Attachment width of metal | |
|---|---|---|
| | member (mm) | Result of probing |
| 11 | 40 | A |
| 12 | 30 | B |
| 13 | 20 | C |
| 14 | 10 | D |

It can be seen from the results described above, that it is suitable to attach the metal member on the entire surface of the circumferential wall of the supporter.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A wafer holder, comprising:
a chuck top for mounting a semiconductor wafer, provided with a heater body; and
a supporter supporting the chuck top, at least partially covered with a metal member.

2. The wafer holder according to claim 1, wherein
said metal member covers said supporter apart by a distance of at most 5 mm from the supporter.

3. The wafer holder according to claim 2, wherein
said metal member covers said supporter apart by a distance of at most 1 mm from the supporter.

4. The wafer holder according to claim 3, wherein
said metal member covers said supporter apart by a distance of at most 0.2 mm from the supporter.

5. A heater unit for a wafer prober, comprising the wafer holder in accordance with claim 1.

6. A wafer prober comprising the heater unit in accordance with claim 5.
